(19) United States
(12) Patent Application Publication
(10) Pub. No.: US 2024/0234193 A9
(43) Pub. Date: Jul. 11, 2024

(54) WAFER PROCESSING APPARATUS

(71) Applicant: Samsung Electronics Co., Ltd., Suwon-si (KR)

(72) Inventors: Youngho Hwang, Suwon-si (KR); Sanghyun Lim, Suwon-si (KR); Jaehong Lim, Suwon-si (KR)

(21) Appl. No.: 18/242,388

(22) Filed: Sep. 5, 2023

(30) Foreign Application Priority Data
Oct. 20, 2022 (KR) 10-2022-0135849

(51) Int. Cl. H01L 21/683; H01L 21/67; H01L 21/687

(52) U.S. Cl. CPC H01L 21/6838; H01L 21/67109; H01L 21/67248; H01L 21/6875

(57) ABSTRACT

Provided is a wafer processing apparatus including a plate having a plurality of support pins configured such that a wafer is mounted on the plurality of support pins and a plurality of vacuum ports positioned between the plurality of support pins, a heater configured to heat the plate, a flow regulator configured to provide a vacuum pressure for fixing the wafer to the plurality of vacuum ports, and configured to adjust a flow rate of a fluid flowing into the plurality of vacuum ports to be a target flow rate, and a chuck controller configured to control the target flow of the fluid set in the flow regulator, wherein the chuck controller is configured to generate a flow control signal for reducing the target flow rate of the fluid and send the flow control signal to the flow regulator during a heating process of the wafer.

### CROSS-REFERENCE TO RELATED APPLICATION

This application is based on and claims priority under 35 U.S.C. § 119 to Korean Patent Application No. 10-2022-0135849, filed on Oct. 20, 2022, in the Korean Intellectual Property Office, the disclosure of which is incorporated by reference herein in its entirety.

### BACKGROUND

The inventive concept relates to a wafer processing apparatus, and more particularly, to a wafer processing apparatus that improves the temperature uniformity of a wafer in a heating process.

In order to manufacture semiconductor devices, various processes such as oxidation processes, photolithography, etching, thin film deposition, metallization, and electrical die sorting (EDS) and packaging are performed on wafers. As the semiconductor devices become increasingly miniaturized, the need for high precision control of semiconductor process conditions is increasingly raised. In particular, at each stage of processing, identifying the warpage of wafers, determining the degree of the warpage of wafers, and implementing uniform process conditions in response to the warpage of wafers are key factors in enhancing semiconductor manufacturing yield.

### SUMMARY

Aspects of the inventive concept provides a wafer processing apparatus capable of uniformly controlling the temperature of an entire wafer.

Aspects of the inventive concept provides a wafer processing apparatus capable of adjusting a vacuum pressure according to a state of a wafer.

In addition, issues to be addressed by the technical idea of the inventive concept are not limited to the issues described above, and other issues may be clearly understood by those of ordinary skill in the art from the following description.

According to an aspect of the inventive concept, there is provided a wafer processing apparatus comprising: a plate having a plurality of support pins configured such that a wafer is mounted on the plurality of support pins and a plurality of vacuum ports positioned between the plurality of support pins; a heater configured to heat the plate; a flow rate regulator configured to provide a vacuum pressure for fixing the wafer to the plurality of vacuum ports, and configured to adjust a flow rate of a fluid flowing into the plurality of vacuum ports to be a target flow rate; and a chuck controller configured to control the target flow rate of the fluid by controlling the flow rate regulator, wherein the chuck controller is configured to generate a flow control signal for reducing the target flow rate of the fluid and send the flow control signal to the flow rate regulator during a heating process of the wafer.

According to another aspect of the inventive concept, there is provided a wafer processing apparatus including a plate having a plurality of support pins configured such that a wafer is mounted on the plurality of support pins and a plurality of vacuum ports positioned between the plurality of support pins, a heater configured to heat the plate, a flow regulator configured to provide a vacuum pressure for fixing the wafer to the plurality of vacuum ports, and configured to adjust a flow of a fluid flowing into the plurality of vacuum ports to be a target flow rate, a pressure sensor arranged in the flow regulator and configured to measure the vacuum pressure, and a chuck controller configured to control the target flow rate of the fluid set in the flow regulator, wherein the chuck controller is configured to generate a flow control signal for controlling the target flow rate of the fluid set in the flow regulator during heating the wafer so that the vacuum pressure is constant.

According to another aspect of the inventive concept, there is provided a wafer processing apparatus including a plate which is divided into a central area and an edge area surrounding the central area and has a plurality of support pins configured such that a wafer is mounted on the plurality of support pins and a plurality of vacuum ports positioned between the plurality of support pins, a heater configured to heat the plate, a flow controller configured to provide a vacuum pressure for fixing the wafer to the plurality of vacuum ports, and adjust a flow of a fluid flowing into the plurality of vacuum ports to be a target flow rate, a pressure sensor arranged in the flow regulator and configured to measure the vacuum pressure; a distance sensor for measuring a separation distance between a lower surface of the wafer and an upper surface of the plate in the edge area, and a chuck controller configured to control the target flow rate of the fluid set in the flow regulator, wherein the plurality of vacuum ports are located in the edge area, the distance sensor and the pressure sensor transfer measured data to the chuck controller, and the chuck controller is configured to generate a flow control signal for controlling the target flow rate of the fluid set in the flow regulator such that the vacuum pressure is constant during a heating process of the wafer.

### BRIEF DESCRIPTION OF THE DRAWINGS

Embodiments of the inventive concept will be more clearly understood from the following detailed description taken in conjunction with the accompanying drawings in which:

FIG. 1 is a diagram illustrating a wafer processing apparatus according to some embodiments.

FIG. 2 is a plan view illustrating a heating plate according to some embodiments.

FIG. 3 is a graph illustrating a flow rate of a fluid controlled by an electronic flow regulator of the wafer processing apparatus of FIG. 1 over time.

FIG. 4 is a diagram illustrating a wafer processing apparatus according to some embodiments.

FIG. 5 is a graph illustrating a flow rate of a fluid controlled by an electronic flow regulator in relation to a temperature of the wafer processing apparatus of FIG. 4;

FIG. 6 is a diagram illustrating a wafer processing apparatus according to some embodiments;

FIG. 7 is a graph illustrating a flow rate of a fluid controlled by an electronic flow regulator in relation to a wafer unbending degree of the wafer processing apparatus of FIG. 6;

FIG. 8 is a diagram illustrating a wafer processing apparatus according to some embodiments.

FIG. 9 is a graph illustrating a flow rate of a fluid controlled by an electronic flow regulator of the wafer processing apparatus of FIG. 8 over time;

FIG. 10 is a diagram illustrating a wafer processing apparatus according to some embodiments;

FIG. 11 is a graph illustrating a flow rate of a fluid controlled by an electronic flow regulator of the wafer processing apparatus of FIG. 10 over time;

FIG. 12 is a schematic perspective view illustrating a baking apparatus according to some embodiments.

FIG. 13 is a block diagram illustrating a system including a baking apparatus according to some embodiments.

### DETAILED DESCRIPTION OF THE EMBODIMENTS

Since the present embodiments may undergo various changes and have various forms, some embodiments will be illustrated in the drawings and described in detail. However, this is not intended to limit the present embodiments to a specific form of disclosure.

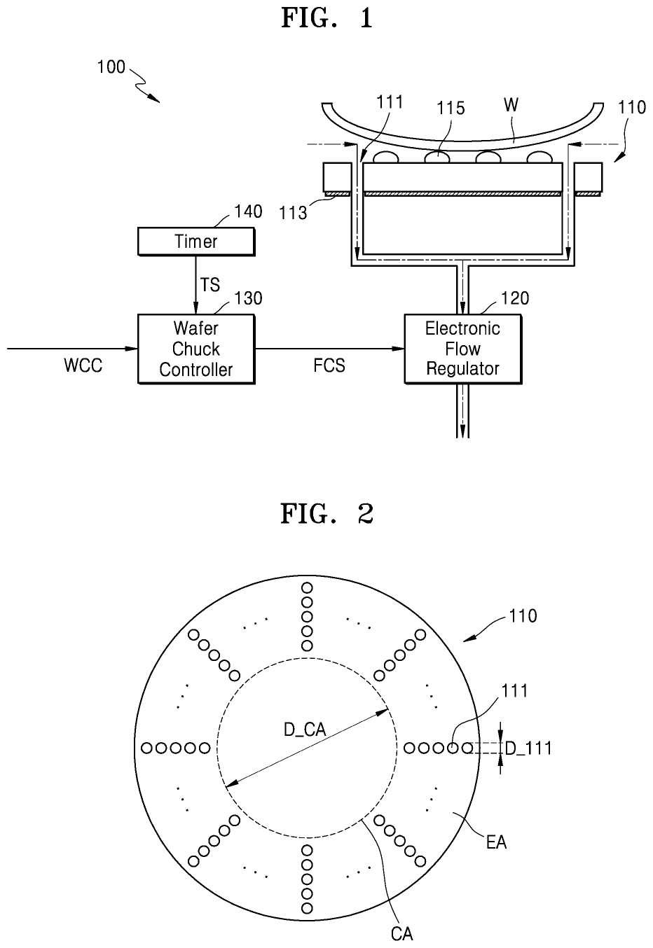

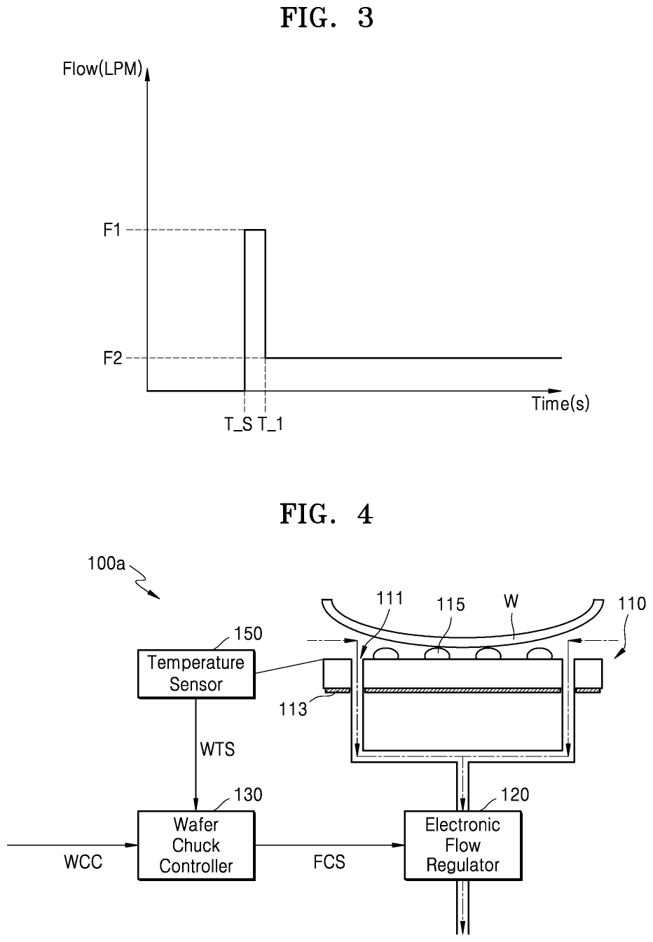

FIG. 1 is a diagram illustrating a wafer processing apparatus according to some embodiments. FIG. 2 is a plan view illustrating a heating plate according to some embodiments. FIG. 3 is a graph illustrating a flow rate of a fluid controlled by an electronic flow regulator of the wafer processing apparatus of FIG. 1 over time.

Referring to FIGS. 1 to 3, a wafer processing apparatus 100 may include a heating plate 110, a heating device 113, an electronic flow regulator 120, and a wafer chuck controller 130.

The heating plate 110 of the wafer processing apparatus 100 may include a plurality of vacuum ports 111 and a plurality of support pins 115. The heating plate 110 may be configured to mount a wafer W on the heating plate 110. For example, the wafer W may be arranged on the heating plate 110, e.g., while the wafer W is processed. According to some embodiments, the heating plate 110 may heat the wafer W to a set temperature. For example, the heating plate 110 may be a plate configured to heat the wafer W on which a process is performed while the wafer W is loaded on the heating plate 110. For example, the heating plate may be a plate configured to be heated by the heating device 113. According to some embodiments, the heating plate 110 may support and fix the wafer W while various semiconductor device manufacturing processes are performed on the wafer W, and maintain the temperature of the wafer W at a set temperature, e.g., a predetermined temperature.

Referring to FIG. 1, the wafer W is shown to be convex in a downward direction, for example, a direction toward the heating plate 110, but the present disclosure is not limited thereto. The wafer W may be convex upward or may have a saddle shape.

Spatially relative terms, such as “beneath,” “below,” “lower,” “above,” “upper,” “downward,” “upward” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The heating plate 110 may have a plurality of vacuum ports 111 provided with vacuum pressure from the outside, e.g., during a process performed on the wafer W. The plurality of vacuum ports 111 extend to the lower surface from the upper surface of the heating plate 110 through the heating plate and serve as a path for providing vacuum pressure. The plurality of vacuum ports 111 may be positioned between the plurality of support pins 115. In FIG. 1, the vacuum pressure is indicated by dashed-arrows. According to some embodiments, the plurality of vacuum ports 111 may be formed in the heating plate 110 to have various arrangements. An example arrangement of the plurality of vacuum ports 111 will be described later with reference to FIG. 2. The plurality of vacuum ports 111 may suction the wafer W through/using vacuum pressure so that the wafer W is fixed on the plurality of support pins 115.

The plurality of support pins 115 of the heating plate 110 may be arranged on the upper surface of the heating plate 110. The plurality of support pins 115 may support the wafer W arranged on the heating plate 110. For example, the wafer W may be mounted on the plurality of support pins 115. The plurality of support pins 115 prevent the wafer W from contacting the heating plate 110, thereby preventing the wafer W from being contaminated by the heating plate 110.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

While a wafer W is mounted on the wafer processing apparatus 100 and supported by the heating plate 110, processes that may be performed on the wafer W may include or may be i) a thermal oxidation process to form an oxide film on the wafer, ii) a lithographic process including spin coating, exposure and development, iii) a thin film deposition process, and/or iv) a dry or wet etching process. For example, the heating plate 110 may be a chuck for supporting the wafer W and maintaining the temperature of the wafer W in any semiconductor device manufacturing process in which the temperature of the wafer W is controlled to be maintained at a set/predetermined temperature.

The thin film deposition process that may be performed on a wafer W may include or may be any one of, for example, Atomic Layer Deposition (ALD), Chemical Vapor Deposition (CVD), Plasma-Enhanced CVD (PECVD), Metal Organic CVD (MOCVD), Physical Vapor Deposition (PVD), Reactive Pulsed Laser Deposition, molecular beam epitaxy, and DC magnetron sputtering.

The dry etching process that may be performed on a wafer W may include or may be any one of reactive ion etching (ME), deep machine RIE (DRIE), ion beam etching (IBE), and AR milling. As another example, the dry etching process that may be performed on the wafer W may be atomic layer etching (ALE). The wet etching process which may be performed on a wafer W may include or may be an etching process using at least one of Cl₂, Al, CHF₃, CH₂F₂, CH₃F, H₂, BCl₃, SiCl₄, Br₂, HBr, NF₃, CF₄, C₂F₆, C₄F₈, SF₆, O₂, SO₂, and COS as an etchant gas.

In some embodiments, a planarization process such as a chemical mechanical polish (CMP) process, an ion implantation process, a photolithography process, and the like may be performed on the wafer W.

The wafer W may include, for example, silicon (Si). The wafer W may include a semiconductor element, such as germanium (Ge), or a compound semiconductor, such as silicon carbide (SiC), gallium arsenide (GaAs), indium arsenide (InAs), and indium phosphide (InP). According to some embodiments, the wafer W may have a silicon on insulator (SOI) structure. The wafer W may include a buried oxide layer. According to some embodiments, the wafer W may include a conductive region, for example, a well doped with impurities. According to some embodiments, the wafer W may have various device isolation structures, such as shallow trench isolation (STI) that separates doped wells from each other. The wafer W may have a first surface which is an active surface and a second surface which is an inactive surface opposite to the first surface. The wafer W may be arranged on the heating plate 110 such that the second surface faces the heating plate 110.

The heating device 113 of the wafer processing apparatus 100 may heat the heating plate 110. For example, the heating device 113 may be a heater configured to heat the heating plate 110. According to some embodiments, the heating device 113 having a thin plate shape may be arranged under the heating plate 110. However, the embodiments are not limited thereto, and the heating device 113 may be provided inside or above the heating plate 110. The heating device 113 may be, for example, an electric heating device, and may have any various shapes to provide uniform heat to the wafer W mounted on the heating plate 110.

The electronic flow regulator 120 of the wafer processing apparatus 100 may provide vacuum pressure to the plurality of vacuum ports 111. The wafer processing apparatus 100 may fix the wafer W to the heating plate 110 through/using vacuum pressure. The electronic flow regulator 120 may adjust the flow rate of the fluid flowing into the plurality of vacuum ports 111 to be a target/predetermined flow rate and/or to be a target/predetermined pressure. The electronic flow regulator 120 may adjust the strength of the vacuum pressure by adjusting the flow rate of the fluid flowing into the plurality of vacuum ports 111. For example, the electronic flow regulator 120 may be a flow regulator regulating a fluid flow electronically and/or digitally.

In some embodiments, the electronic flow regulator 120 may adjust the flow rate of the fluid flowing into the plurality of vacuum ports 111 based on a flow control signal FCS. According to some embodiments, the electronic flow regulator 120 may include a servo valve or a solenoid valve.

The wafer chuck controller 130 of the wafer processing apparatus 100 may control the electronic flow regulator 120. The wafer chuck controller 130 may generate a flow control signal for decreasing the target flow rate of the electronic flow regulator 120 during the heating process of the wafer. For example, the wafer chuck controller 130 may control the electronic flow controller by generating a flow control signal FCS based on an external wafer chucking command WCC. For example, the wafer chuck controller 130 in the present disclosure may be a chuck controller configured to control an overall operation of a chuck (e.g., a plate on which a wafer W is loaded/fixed) to hold a wafer W on the chuck. For example, the electronic flow regulator 120 may receive a signal including a target flow rate of the fluid, and the wafer chuck controller 130 may change/replace signal including the target flow rate of the fluid of the electronic flow regulator 120 over time, e.g., while a process is performed. For example, the target flow or the target flow rate of the electronic flow regulator 120 in the present disclosure may be a value of a target flow rate of the fluid included in an electrical signal sent from the wafer chuck controller 130 to the electronic flow regulator 120 and/or a value stored in a memory included in the electronic flow regulator 120. For example, the target flow rate of the electronic flow regulator 120 may be the target flow rate of the fluid set within a memory included in the electronic flow regulator 120. In certain embodiments, the target flow rate of the electronic flow regulator 120 may be a target flow rate of the fluid controlled by the wafer chuck controller 130 using the electronic flow regulator 120 in real time.

In some embodiments, the wafer chuck controller 130 may generate a flow control signal FCS, which is a signal for controlling the electronic flow regulator 120 based on a timing signal TS of a timer 140. An example related to generation of a flow control signal through the timer 140 will be described later with reference to FIG. 3.

Referring to FIG. 2, the heating plate 110 may be divided into a central area CA and an edge area EA. The edge area EA may surround the central area CA. The plurality of vacuum ports 111 may be located in the edge area EA of the heating plate 110.

In some embodiments, an upper/top surface of the heating plate 110 has a circular shape, and the central area CA may be a circular region containing and surrounding the center point of the upper surface of the heating plate 110. In some embodiments, the central area CA may be a circular region with a radius of approximately 80 mm to approximately 140 mm from the center point of the upper surface of the heating plate 110. The edge area EA may be an area from the central area CA (e.g., from an outer end of the central area CA) to an outer end of an upper surface of the heating plate 110. In some embodiments, the plurality of vacuum ports 111 may be located approximately 80 mm to 140 mm apart from the center point of the upper surface of the heating plate 110.

In some embodiments, the diameters of the plurality of vacuum ports 111, e.g., in a horizontal direction, each may have a first length D_111. The first length D_111 may be in a range from about 0.5 mm to about 2 mm. Although FIG. 2 illustrates that the diameters of the plurality of vacuum ports 111 have the same length, the diameters of the plurality of vacuum ports 111 are not limited thereto, and may have different lengths.

In some embodiments, the plurality of vacuum ports 111 may be arranged in numbers of about five to about twelve in a radial direction with respect to the center point of the heating plate 110. Although FIG. 2 illustrates that five vacuum ports 111 are arranged in a radial direction, embodiments are not limited thereto, and different numbers of vacuum ports 111 may be arranged in a radial direction.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The plurality of vacuum ports 111 of the wafer processing apparatus 100 may be located in the edge area EA of the heating plate 110, and vacuum pressure may be formed in the edge area EA of the heating plate 110. In some configurations, pressure is applied to the edge of the wafer W to unfold/unbend the wafer W bent downward. For example, in order to fix the wafer W in which the warpage phenomenon has occurred to the heating plate 110, a vacuum pressure is formed at the edge of the wafer W. For example, since the central area CA of the wafer W in which the warpage phenomenon occurs is easily fixed to the heating plate 110 even if there is no vacuum pressure, the plurality of vacuum ports 111 may be positioned only in the edge area EA to fix the wafer W to the heating plate 110. However, the present disclosure is not limited thereto, and the vacuum ports 111 may be formed in the central area of the heating plate 110 in certain embodiments.

Referring to FIG. 3, the target flow (or flow rate) of the electronic flow regulator 120 may decrease as the heating process proceeds. For example, the wafer chuck controller 130 may generate a flow control signal FCS with an interval after a start T_S of the heating process, thereby reducing the target flow (or flow rate) of the electronic flow regulator 120.

In some embodiments, the target flow (or flow rate) of the electronic flow regulator 120 may be reduced in the form of a step function. For example, the target flow of the electronic flow regulator 120 may rapidly decrease at a predetermined time.

In some embodiments, the wafer chuck controller 130 may control the target flow of the electronic flow regulator 120 to be the first flowrate F1 at the start T_S of the heating process. The wafer chuck controller 130 may control the target flow of the electronic flow regulator 120 to be a second flow F2 less than the first flow F1 during the heating process. In some embodiments, the first flow F1 may be in a range from about 10 Liter Per Minute (LPM) to about 30 LPM, and the second flow F2 may be in a range from about 2 LPM to about 8 LPM.

In some embodiments, the wafer chuck controller 130 may control the target flow of the electronic flow regulator 120 with an interval after the start T_S of the heating process. For example, the wafer chuck controller 130 may control the target flow of the electronic flow regulator 120 by receiving the timing signal TS from the timer 140 after the start T_S of the heating process and forming/generating the flow control signal FCS. For example, the wafer chuck controller 130 may receive the time signal TS from the timer 140 to reduce the target flow of the electronic flow regulator 120. In some embodiments, the wafer chuck controller 130 may decrease the target flow of the electronic flow regulator 120 with an interval T_1 after the start T_S of the heating process. For example, the interval T_1 may be a time lapse from the start T_S of the heating process to the time T_1. In some embodiments, the interval T_1 may be in a range from about 2 seconds to about 8 seconds.

In some embodiments, the wafer W mounted on the wafer processing apparatus 100 may have a downward convex shape. For example, the wafer W may be mounted on the wafer processing apparatus 100 in a state in which a warpage phenomenon occurs. The warped wafer W may be fixed to the heating plate 110 by vacuum pressure. The warped wafer W may be unfolded (unbend) over time by vacuum pressure. In some embodiments, vacuum pressure may be formed in the plurality of vacuum ports 111 at the start of the heating process of the wafer W. For example, the wafer W mounted on the wafer processing apparatus 100 may be unfolded while a heating process is performed. As the wafer W is unfolded, the distance between the wafer W and the heating plate 110 at the edge of the wafer W may be reduced. When the separation distance between the wafer W and the heating plate 110 decreases at the edge of the wafer W, the vacuum pressure may increase even if the target flow of the electronic flow regulator 120 is constant. For example, after a certain period of time elapses after the heating process of the wafer W begins, the warped wafer W is smoothed or unbends, and even if the target flow of the electronic flow regulator 120 is reduced, the vacuum pressure for fixing the wafer W may be constant. As the flow flowing into the plurality of vacuum ports 111 increases, unnecessary turbulence of the fluid may occur at the edge of the wafer W, and the temperature of the wafer W may be uneven. The wafer processing apparatus 100 of an aspect of the inventive concept may uniformly heat the wafer W by reducing the flow flowing into the plurality of vacuum ports 111 before the wafer W reaches a process temperature.

The wafer chuck controller 130 may be implemented in hardware, firmware, software, or any combination thereof. For example, the wafer chuck controller 130 may be a computing device (e.g., a computer) such as a workstation computer, a desktop computer, a laptop computer, and a tablet computer. The wafer chuck controller 130 may include or may be a simple controller, a complicated processor such as a microprocessor, a CPU, a GPU, or the like, a processor configured by software, dedicated hardware, or firmware. In some embodiments, the wafer chuck controller 130 may be implemented by a general-purpose computer or application-specific hardware such as a digital signal processor (DSP), a field programmable gate array (FPGA), and an application specific integrated circuit (ASIC).

In some embodiments, the operation of the wafer chuck controller 130 may be implemented as instructions stored on a machine-readable medium that may be read and executed by one or more processors. Here, the machine-readable medium may include or may be any mechanism for storing and/or transmitting information in a form readable by a machine (e.g., a computing device). For example, machine-readable media may include or may be read only memory (ROM), random access memory (RAM), magnetic disk storage media, optical storage media, and/or flash memory devices.

Firmware, software, routines, and instructions may also be configured to perform the operation described for wafer chuck controller 130, or the operation for performing any process described below. For example, the wafer chuck controller 130 may be implemented by software that generates signals for processing the wafer W, and performs functions that receive data, perform predetermined operations to adjust the process, and the like.

However, this is for convenience of explanation, and the operation of the wafer chuck controller 130 described above may be performed by a computing device, a processor, a controller, or other devices that execute firmware, software, routines, instructions, etc.

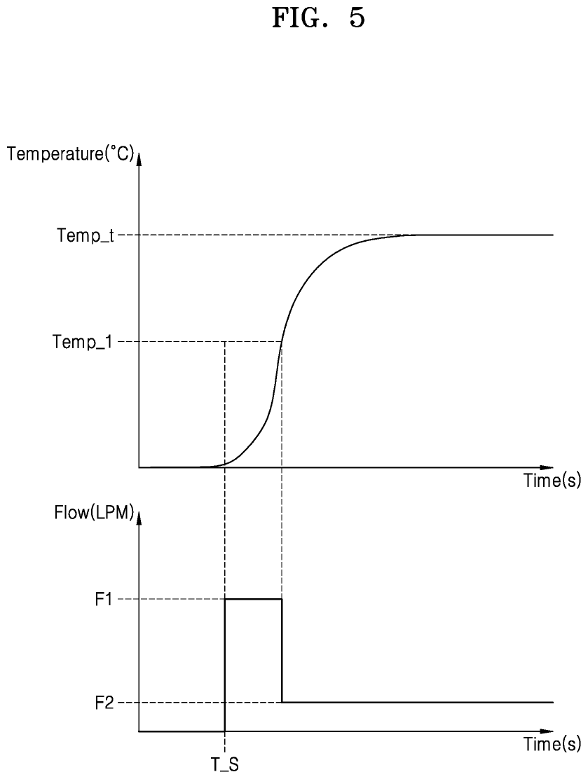

FIG. 4 is a diagram illustrating a wafer processing apparatus according to some embodiments. FIG. 5 is a graph illustrating a target flow of an electronic flow regulator in relation to a temperature of the wafer processing apparatus of FIG. 4.

Hereinafter, repetitive descriptions between the wafer processing apparatus 100a of FIGS. 4 and 5 and the wafer processing apparatus 100 of FIG. 1 will be omitted and differences therebetween will be mainly described. Therefore, features of the wafer processing apparatus 100a not described herein may be the same as the features of the wafer processing apparatus 100 unless the context indicates otherwise.

Referring to FIGS. 4 and 5, the wafer processing apparatus 100a may further include a temperature sensor 150. The temperature sensor 150 may measure the temperature of the wafer W during the heating process of the wafer W. The temperature sensor 150 may be embedded in the heating plate 110. However, the embodiments are not limited thereto, and the temperature sensor 150 may be arranged on an upper surface or a lower surface of the heating plate 110. In certain embodiments, the temperature sensor 150 may be a non-contact temperature sensor, and may be spaced apart from the heating plate 110. For example, the temperature sensor 150 may detect the temperature of the heating plate 110 by analyzing electromagnetic wave spectrums emitted from the heating plate 110 in certain embodiments.

In some embodiments, the temperature sensor 150 may send a temperature signal WTS to the wafer chuck controller 130 when the temperature of the wafer W reaches a predetermined temperature. The wafer chuck controller 130 receiving the temperature signal WTS may control the flow of the electronic flow regulator 120 by generating a flow control signal FCS. In some embodiments, the temperature sensor 150 may transmit a temperature signal WTS to the wafer chuck controller 130 when the temperature of the wafer W reaches a first temperature Temp_1. In some embodiments, the first temperature Temp_1 may be about 30% to about 80% of the target temperature Tempt of the heating process of the wafer W, e.g., in Celsius. In some embodiments, the target temperature Tempt may be about 70° C. to about 500° C. The first temperature Temp_1 may be about 20° C. to about 400° C.

In some embodiments, at the start T_S of the heating process of the wafer processing apparatus 100, the target flow of the electronic flow regulator 120 may be the first flow rate F1. When the temperature of the wafer W measured by the temperature sensor 150 during the heating process reaches the first temperature Temp_1, the wafer chuck controller 130 may adjust the target flow of the electronic flow regulator 120 to a second flow F2 less than the first flow F1. In some embodiments, the first flow F1 may be in a range from about 10 LPM to about 30 LPM, and the second flow F2 may be in a range from about 2 LPM to about 8 LPM.

The wafer chuck controller 130 of the present embodiments may reduce the target flow of the electronic flow regulator 120 before reaching the target temperature Tempt. While a wafer W is heated through/by the heating plate 110 in a state in which the wafer W is fixed by a vacuum pressure applied to the wafer W, the temperature of the wafer W may increase and the separation distance between the wafer W and the heating plate 110 may decrease. When the separation distance between the heating plate 110 and the wafer W decreases, the vacuum pressure increases at the same flow of the fluid controlled by the electronic flow regulator 120, and the vacuum pressure may be maintained even if the target flow of the electronic flow regulator 120 for fixing the wafer W decreases. When the wafer W reaches the first temperature Temp_1 which is about 30% to about 80% of the target temperature Tempt, the separation distance between the wafer W and the heating plate 110 is less than the separation distance at the start T_S of the heating process, so that the wafer W may be fixed even by reducing the target flow of the electronic flow regulator 120. The wafer W may be uniformly heated by reducing the flow flowing into the plurality of vacuum ports 111 before the wafer W reaches the target temperature Tempt.

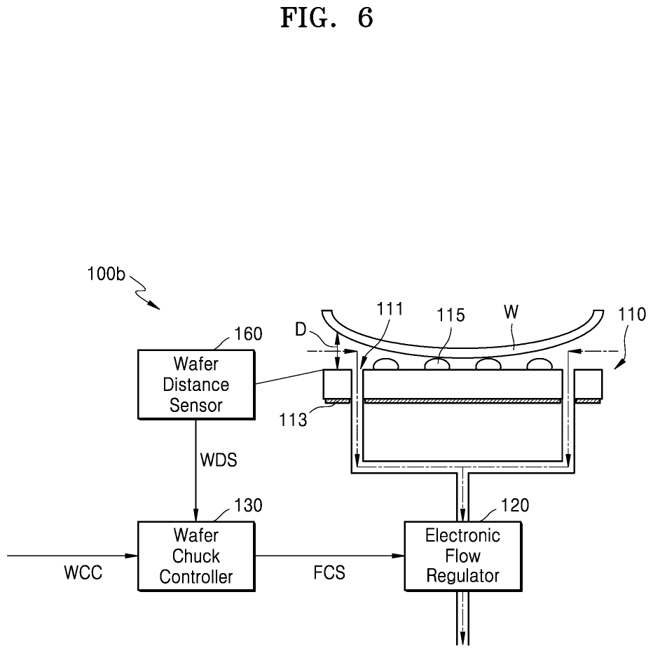

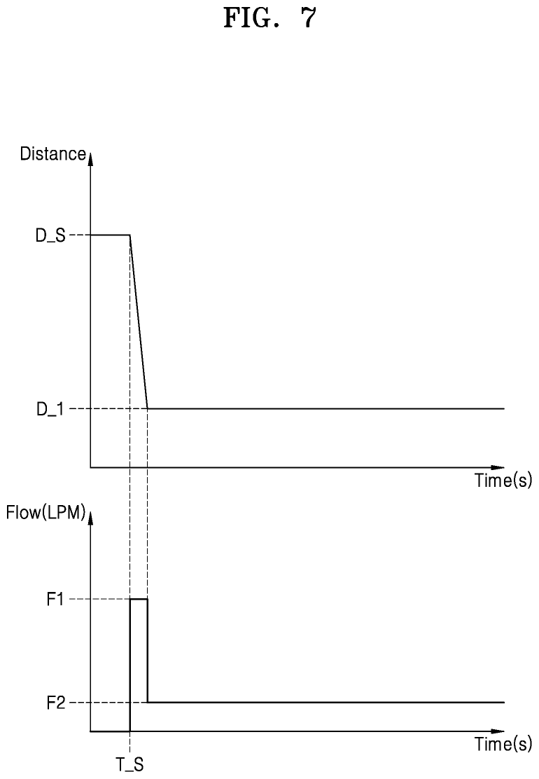

FIG. 6 is a diagram illustrating a wafer processing apparatus according to some embodiments. FIG. 7 is a graph illustrating a target flow of an electronic flow regulator in relation to a wafer unbending degree of the wafer processing apparatus of FIG. 6.

Hereinafter, repetitive descriptions between the wafer processing apparatus 100b of FIGS. 6 and 7 and the wafer processing apparatus 100 of FIG. 1 will be omitted and differences therebetween will be mainly described. Therefore, features of the wafer processing apparatus 100b not described herein may be the same as the features of the wafer processing apparatus 100 unless the context indicates otherwise.

Referring to FIGS. 6 and 7, the wafer processing apparatus 100b may further include a distance sensor 160. The distance sensor 160 may measure the separation distance D between a lower surface of the wafer W and an upper surface of the heating plate 110.

In some embodiments, when the wafer W is convex downward due to warpage, the distance sensor 160 may measure the separation distance D between the lower surface of the wafer W and the upper surface of the heating plate 110 at the edge of the wafer W. The value measured through/by the distance sensor 160 may be determined to be the degree to which the wafer W is unfolded. In an embodiment, the distance sensor 160 may be an optical sensor that measures the separation distance D through/using light, e.g., a laser. In an embodiment, the distance sensor 160 may be positioned on an upper surface of the heating plate 110.

In an embodiment, the distance sensor 160 may transmit a distance signal WDS to the wafer chuck controller 130 when the separation distance D between the wafer W and the heating plate 110 reaches a predetermined distance. The wafer chuck controller 130 receiving the distance signal WDS may control the target flow of the electronic flow regulator 120 by generating the flow control signal FCS. In some embodiments, the distance sensor 160 may send a distance signal WDS to the wafer chuck controller 130 when the separation distance D between the wafer W and the heating plate 110 becomes a first distance D_1. When the separation distance D between the lower surface of the wafer W and the upper surface of the heating plate 110 measured by the distance sensor 160 is a reference distance D S at the start of the heating process, the first distance D_1 may be less than the reference distance D S. In some embodiments, the first distance D_1 may be in a range from about 50 μm to about 200 μm. For example, the first distance D_1 may be set to be between 50 μm and 200 μm.

In some embodiments, at the start T_S of the heating process of the wafer processing apparatus 100b, the target flow of the electronic flow regulator 120 may be the first flow rate F1, and the separation distance D between the wafer W and the heating plate 110 may be the reference distance D S. When the separation distance D between the lower surface of the wafer W measured by the distance sensor 160 and the upper surface of the heating plate 110 becomes a first distance D_1 less than the reference distance D S, during the heating process, the wafer chuck controller 130 may adjust the target flow of the electronic flow regulator 120 to a second flow F2. In some embodiments, the first flow F1 may be in a range from about 10 LPM to about 30 LPM, and the second flow F2 may be in a range from about 2 LPM to about 8 LPM.

When the separation distance D between the wafer W and the heating plate 110 decreases, the wafer chuck controller 130 may reduce the target flow of the electronic flow regulator 120. When the separation distance D between the wafer W and the heating plate 110 is reduced, the vacuum pressure may be maintained even if the target flow of the electronic flow regulator 120 decreases. In some embodiments, when the downward convex wafer W is unfolded by the warpage phenomenon, and the separation distance D between the wafer W and the heating plate 110 becomes the first distance D_1, the wafer W may be fixed even by reducing the target flow of the electronic flow regulator 120. The wafer processing apparatus 100 of the embodiments may uniformly heat the wafer W by reducing the flow flowing into the plurality of vacuum ports 111 when the wafer W is unfolded to a predetermined level or more.

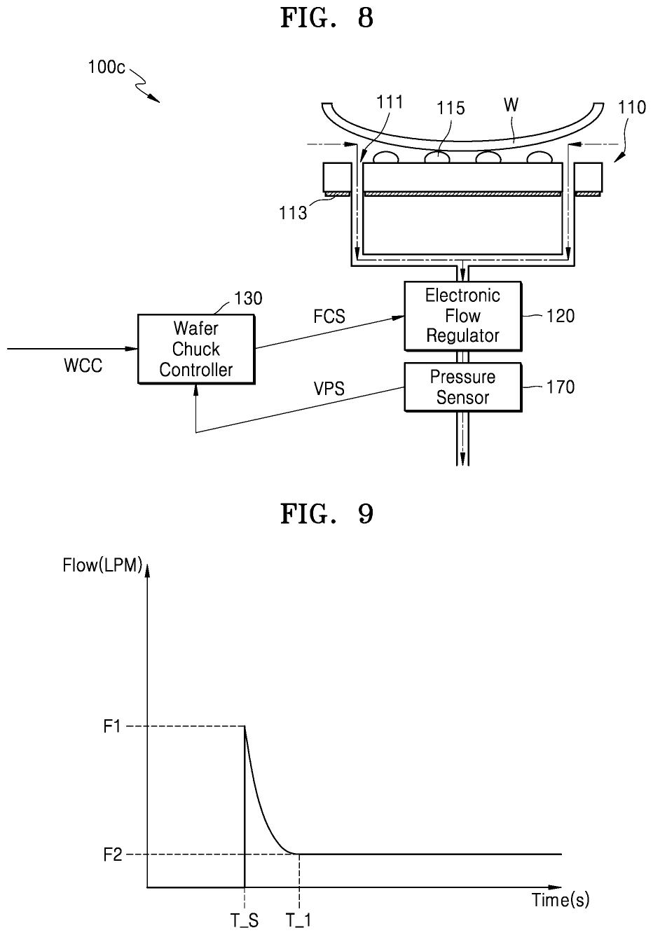

FIG. 8 is a diagram illustrating a wafer processing apparatus according to some embodiments. FIG. 9 is a graph illustrating a target flow of an electronic flow regulator of the wafer processing apparatus of FIG. 8 over time.

Referring to FIGS. 8 and 9, the wafer processing apparatus 100c may include a heating plate 110, a heating device 113, an electronic flow regulator 120, a pressure sensor 170, and a wafer chuck controller 130.

The heating plate 110, the heating device 113, and the electronic flow regulator 120 of the wafer processing device 100c may be respectively the same as the heating plate 110, the heating device 113, and the electronic flow regulator 120 of FIG. 1.

The pressure sensor 170 of the wafer processing apparatus 100c may be arranged in the electronic flow regulator 120. The pressure sensor 170 may measure a vacuum pressure for fixing the wafer W, e.g., the pressure in the vacuum ports 111. In some embodiments, the pressure sensor 170 may measure the vacuum pressure during the heating process and transmit a pressure signal VPS to the wafer chuck controller 130. The wafer chuck controller 130 may control a target flow of the electronic flow regulator 120 based on the pressure signal VPS received from the pressure sensor 170.

The wafer chuck controller 130 of the wafer processing apparatus 100c may control the electronic flow regulator 120. The wafer chuck controller 130 may generate a flow control signal FCS that controls the target flow of the electronic flow regulator 120 so that the vacuum pressure is constant during the heating process. In some embodiments, the flow control signal FCS may gradually decrease the target flow of the electronic flow regulator 120 with relation to the progress of the heating process. In some embodiments, the wafer chuck controller 130 may be the same as the wafer chuck controller 130 described in FIG. 1.

In some embodiments, as the heating process of the wafer W proceeds, the wafer W, which has a convex shape, is unfolded from the warpage phenomenon by vacuum pressure, and thus the separation distance between the wafer W and the heating plate 110 may be reduced. As the separation distance between the wafer W and the heating plate 110 decreases, the vacuum pressure may increase at the same flow of the electronic flow regulator 120. As the heating process proceeds, in order to keep the vacuum pressure measured through/by the pressure sensor 170 constant, the wafer chuck controller 130 may reduce the target flow of the electronic flow regulator 120.

In some embodiments, the wafer chuck controller 130 may control the target flow of the electronic flow regulator 120 to be the first flow F1 at the start T_S of the heating process. As the heating process proceeds, the wafer chuck controller 130 may gradually reduce the target flow of the electronic flow regulator 120 to become the second flow F2. In some embodiments, the target flow of the electronic flow regulator 120 may be a second flow F2 with an interval T_1 after the start T_S of the heating process. For example, the interval T_1 may be a time lapse from the start T_S of the heating process to the time T_1. In some embodiments, the first flow F1 may be in a range from about 10 LPM to about 30 LPM, and the second flow F2 may be in a range from about 2 LPM to about 8 LPM. In some embodiments, the interval T_1 may be in a range from about 2 seconds to about 8 seconds. Although FIG. 9 illustrates that the target flow of the electronic flow regulator 120 decreases in a curved line over time, the target flow of the electronic flow regulator 120 is not limited thereto, and may decrease in a straight line over time. For example, the target flow of the electronic flow regulator 120 may linearly decrease over time.

In the wafer processing apparatus 100c of the present embodiment, as the wafer W is unfolded by vacuum pressure, the vacuum pressure may be kept constant even if the separation distance between the wafer W and the heating plate 110 varies. When the vacuum pressure is kept constant, the wafer W is fixed to the heating plate 110, and the target flow of the electronic flow regulator 120 is reduced, thereby suppressing the generation of unnecessary turbulence of the fluid at the edge of the wafer W. The wafer processing apparatus 100c may uniformly heat the wafer W by maintaining an appropriate vacuum pressure and suppressing the generation of unnecessary turbulence of the fluid.

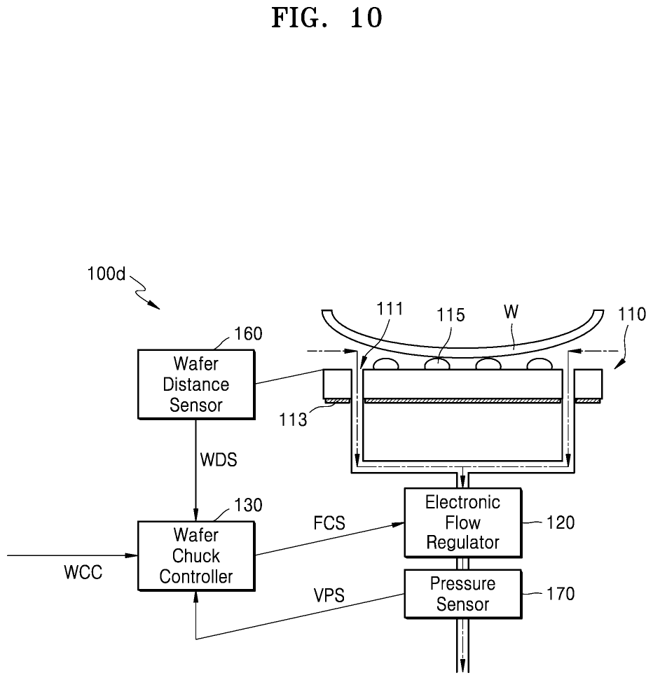

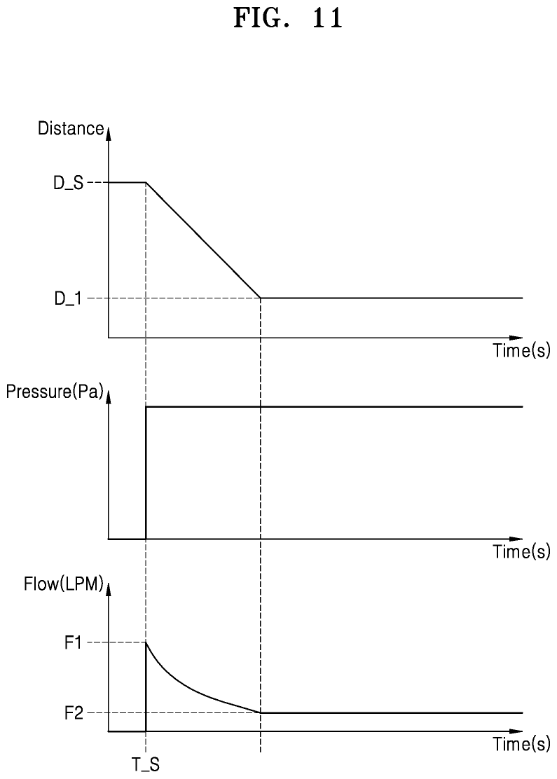

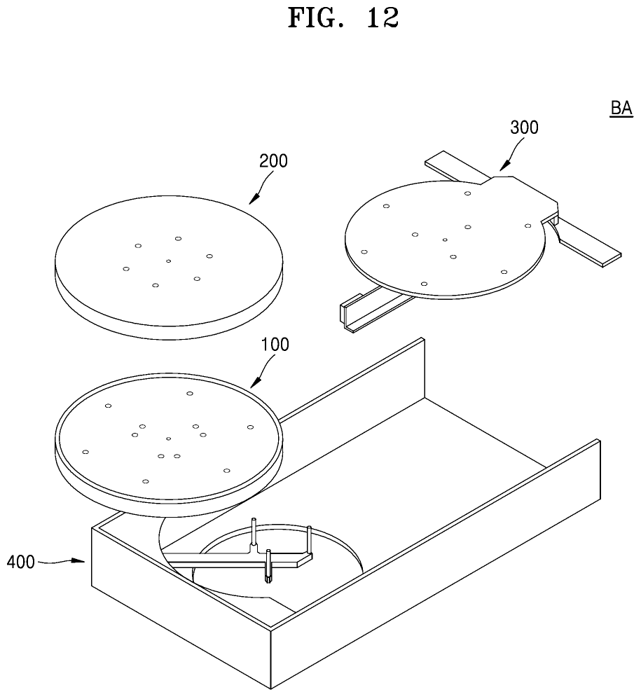

FIG. 10 is a diagram illustrating a wafer processing apparatus according to some embodiments. FIG. 11 is a graph illustrating a target flow of an electronic flow regulator of the wafer processing apparatus of FIG. 10 over time.

Hereinafter, repetitive descriptions between the wafer processing apparatus 100d of FIGS. 10 and 11 and the wafer processing apparatus 100c of FIG. 8 will be omitted and differences therebetween will be mainly described. Therefore, features of the wafer processing apparatus 100d not described herein may be the same as the features of the wafer processing apparatus 100c unless the context indicates otherwise.

Referring to FIGS. 10 and 11, the wafer processing apparatus 100d may further include a distance sensor 160. The distance sensor 160 may measure a separation distance D between the wafer W and the heating plate 110. In some embodiments, when the wafer W is convex downward due to warpage, the distance sensor 160 may measure the separation distance D between the wafer W and the heating plate 110 at the edge of the wafer W. The value measured through/by the distance sensor 160 may be determined to be the degree to which the wafer W is unfolded.

In some embodiments, the distance sensor 160 may transmit a distance signal/information WDS to the wafer chuck controller 130 when the separation distance D between the wafer W and the heating plate 110 reaches a predetermined distance. When receiving the distance signal/information WDS, the wafer chuck controller 130 may send a flow control signal FCS to the electronic flow regulator 120 to maintain the vacuum pressure measured by the pressure sensor 170 during the heating process. For example, the wafer chuck controller 130 may generate a flow control signal FCS to keep the vacuum pressure formed in the plurality of vacuum ports 111 constant during the heating process when the separation distance between the wafer W and the heating plate 110 reaches a certain/predetermined distance.

In some embodiments, at the start T_S of the heating process, the target flow of the electronic flow regulator 120 may be a first flow F1. As the heating process proceeds, the separation distance D between the wafer W and the heating plate 110 may be reduced as the wafer W is unfolded by vacuum pressure. The distance sensor 160 may send a distance signal WDS to the wafer chuck controller 130 when the separation distance D between the lower surface of the wafer W and the upper surface of the heating plate 110 becomes less than the reference distance and/or becomes the first distance D_1. When receiving the distance signal WDS, the wafer chuck controller 130 may adjust the target flow of the electronic flow regulator 120 so that the vacuum pressure during the heating process maintains a first pressure. In an embodiment, when the wafer chuck controller 130 receives the distance signal WDS, the target flow of the electronic flow regulator 120 may be a second flow F2 less than the first flow F1. Thereafter, in order to maintain the vacuum pressure constant, the target flow of the electronic flow regulator 120 may be maintained at a second flow F2 during the heating process.

In some embodiments, the target flow of the electronic flow regulator 120 may gradually decrease as the heating process proceeds from the first flow F1 to the second flow F2. For example, the pressure sensor 170 measures vacuum pressure in real time and sends a pressure signal VPS to the wafer chuck controller 130, and the wafer chuck controller 130 may control the target flow of the electronic flow regulator 120 to be constant based on the pressure signal VPS.

In the wafer processing apparatus 100d of the present embodiment, as the wafer W is unfolded by vacuum pressure, the vacuum pressure may be kept constant even if the separation distance between the wafer W and the heating plate 110 varies. When the vacuum pressure is kept constant, the wafer W is fixed to the heating plate 110, and the target flow of the electronic flow regulator 120 is reduced, thereby suppressing the generation of unnecessary turbulence of the fluid at the edge of the wafer W. The wafer processing apparatus 100d may uniformly heat the wafer W by maintaining an appropriate vacuum pressure and suppressing the generation of unnecessary turbulence of the fluid.

FIG. 12 is a schematic perspective view illustrating a baking apparatus BA according to some embodiments.

Referring to FIG. 12, the baking apparatus BA may further include a chamber 200, a transport robot 300, and a base module 400 in addition to the wafer processing apparatus 100 of FIG. 1.

However, the embodiments are not limited thereto, and the baking apparatus BA may include a chamber 200, a conveying robot 300, and a base module 400 in addition to one of the wafer processing devices 100a, 100b, 100c, and 100d of respective FIGS. 4, 6, 8, and 10.

The transport robot 300 may introduce/load a wafer into the baking apparatus BA and/or may unload a processed wafer from the baking apparatus BA.

The chamber 200 may include an exhaust structure for exhausting gas generated while the wafer is heated. The chamber 200 may isolate the wafer from the outside during the process. The chamber 200 may prevent heat for treating the wafer from leaking out of the chamber and prevent the wafer from being contaminated by particles outside the chamber. The chamber 200 may be configured to cover both the heating plate and the wafer or to cover only the wafer.

The base module 400 may support various components included in the baking apparatus, such as the heating plate and the chamber.

When the wafer is delivered by the conveying robot 300, the chamber 200 may be opened, the wafer may be mounted on the heating plate by the conveying robot 300, and the chamber 200 may be closed. Then, when the wafer is sufficiently heated, the chamber 200 is opened again, and the wafer may be carried out by the transport robot 300.

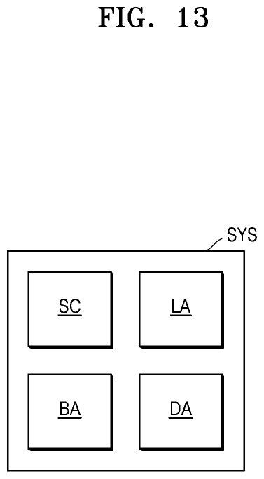

FIG. 13 is a block diagram illustrating a system SYS including a baking apparatus BA according to some embodiments.

Referring to FIG. 13, the system SYS may include a spin coater SC, a lithography apparatus LA, the baking apparatus BA, and a developing apparatus DA.

The process by the system SYS may include the manufacture of a semiconductor device/structure in which a circuit structure is implemented on a semiconductor wafer or another wafer/substrate. The process performed by the system SYS may include, for example, a semiconductor process by Deep Ultra-Violet (DUV) or Extreme UV (EUV).

The spin coater SC may provide a photoresist layer on a semiconductor structure by spin coating.

The baking apparatus BA may be the baking apparatus BA described with reference to FIG. 12. According to some embodiments, the baking apparatus BA may perform a soft baking process after the photoresist layer is applied on the wafer by the spin coater SC. According to some embodiments, the baking apparatus BA may further perform a hard baking process after a post-exposure bake (POB) and a developing device DA after an exposure process by the lithography device LA is performed.

The lithography apparatus LA may perform an EUV lithography process. The lithography apparatus LA may include a measurement station and an exposure station.

The lithography apparatus LA may be a dual stage type apparatus including two wafer tables. The wafer tables may be an exposure station and a measurement station for measurement and exposure, respectively. Accordingly, while the semiconductor structure SS on one wafer table is exposed, pre-exposure measurement of the semiconductor structure SS on another wafer table may be performed. Since it takes a long time to measure an alignment mark, and a lithography process is a bottleneck process of the entire semiconductor process, the productivity of the semiconductor device may be greatly improved by providing two wafer tables. However, the embodiments are not limited thereto, and the lithography apparatus LA may be a mono stage type lithography apparatus including a single wafer table.

The developing apparatus DA may develop the exposed photoresist layer to form a photoresist pattern.

The system SYS may further include an inspection apparatus for post-exposure inspection as necessary. The inspection apparatus may be a scatterometer, such as an angle-resolved scatterometer or a spectroscopic scatterometer.

The system SYS may further include, for example, an etching device. The etching apparatus may etch a wafer using a developed photoresist pattern as an etching mask. According to some other embodiments, the system SYS may further include devices for performing an ion implant process, a deposition process, and the like.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise. For example, each embodiment illustrated in FIGS. 1, 4, 6, 8 and 10 may be combined with one or more components (e.g., the timer 140, the temperature sensor 150, the wafer distance sensor 160, the pressure sensor 170, etc.) included in the other embodiments.

While aspects of the inventive concept has been particularly shown and described with reference to embodiments thereof, it will be understood that various changes in form and details may be made therein without departing from the spirit and scope of the following claims. For example, embodiments of the present disclosure may include a method of manufacturing a semiconductor device using the apparatuses and the processes described above as briefly described in the above embodiments.

What is claimed is:

1. A wafer processing apparatus comprising:
a plate having a plurality of support pins configured such that a wafer is mounted on the plurality of support pins and a plurality of vacuum ports positioned between the plurality of support pins;
a heater configured to heat the plate;
a flow regulator configured to provide a vacuum pressure for fixing the wafer to the plurality of vacuum ports, and configured to adjust a flow rate of a fluid flowing into the plurality of vacuum ports to be a target flow rate; and
a chuck controller configured to control the target flow rate of the fluid by controlling the flow regulator,
wherein the chuck controller is configured to generate a flow control signal for reducing the target flow rate of the fluid and send the flow control signal to the flow regulator during a heating process of the wafer.

2. The wafer processing apparatus of claim 1, wherein
the plate is divided into a central area and an edge area surrounding the central area, and
the plurality of vacuum ports are located in the edge area of the plate.

3. The wafer processing apparatus of claim 2, wherein
the central area is a circular region having a radius of about 80 mm to about 140 mm from a central point of an upper surface of the plate, and
the edge area is a region ranging from an outer end of the central area to an outer end of the plate.

4. The wafer processing apparatus of claim 1, wherein the flow control signal reduces the target flow rate of the fluid set in the flow regulator as a step function.

5. The wafer processing apparatus of claim 1, wherein the chuck controller controls the target flow rate of the fluid set in the flow regulator to be a first flow rate at a start of a heating process of the wafer, and controls the target flow rate of the fluid set in the flow regulator to be a second flow rate during the heating process of the wafer, the second flow rate being less than the first flow rate.

6. The wafer processing apparatus of claim 5, wherein
the first flow rate is in a range from about 10 LPM to about 30 LPM, and
the second flow rate is in a range from about 2 LPM to about 8 LPM.

7. The wafer processing apparatus of claim 1, wherein the chuck controller is configured to control the target flow rate of the fluid set in the flow regulator with an interval after the heating process of the wafer is started.

8. The wafer processing apparatus of claim 7, wherein the interval is in a range from about 2 seconds to about 8 seconds.

9. The wafer processing apparatus of claim 1, further comprising a temperature sensor configured to measure a temperature of the wafer during the heating process of the wafer,
wherein the chuck controller is configured to control the target flow rate of the fluid set in the flow regulator when the temperature of the wafer reaches a first temperature, which is about 30% to about 80% of a target temperature of the heating process in Celsius.

10. The wafer processing apparatus of claim 9, wherein the target temperature is in a range from about 70° C. to about 500° C.

11. The wafer processing apparatus of claim 1, further comprising a distance sensor configured to measure a separation distance between a lower surface of the wafer and an upper surface of the plate.

12. The wafer processing apparatus of claim 11, wherein the wafer processing apparatus is configured such that at a start of the heating process of the wafer, the separation distance measured by the distance sensor is a reference distance, and
the chuck controller is configured to control the target flow rate of the fluid set in the flow regulator when the separation distance between the wafer and the plate reaches a first distance that is smaller than the reference distance.

13. The wafer processing apparatus of claim 12, wherein the first distance is in a range from about 50 μm to about 200 μm.

14. A wafer processing apparatus comprising:
a plate having a plurality of support pins configured such that a wafer is mounted on the plurality of support pins and a plurality of vacuum ports positioned between the plurality of support pins;
a heater configured to heat the plate;
a flow regulator configured to provide a vacuum pressure for fixing the wafer to the plurality of vacuum ports, and adjust a flow rate of a fluid flowing into the plurality of vacuum ports to be a target flow rate;
a pressure sensor arranged in the flow regulator and configured to measure the vacuum pressure; and
a chuck controller configured to control the target flow rate of the fluid set in the flow regulator,
wherein the chuck controller is configured to generate a flow control signal for controlling the target flow rate of the fluid set in the flow regulator during heating of the wafer so that the vacuum pressure is constant.

15. The wafer processing apparatus of claim 14, wherein the flow control signal gradually reduces the target flow rate of the fluid set in the flow regulator over time.

16. The wafer processing apparatus of claim 15, wherein the wafer processing apparatus is configured such that during a heating of the wafer, the maximum flow rate of the target flow rate of the fluid set in the flow regulator is a first flow rate, and the minimum flow rate is a second flow rate,
the first flow rate is in a range from about 10 LPM to about 30 LPM, and
the second flow rate is in a range from about 2 LPM to about 8 LPM.

17. The wafer processing apparatus of claim 14, further comprising a distance sensor configured to measure a separation distance between a lower surface of the wafer and an upper surface of the plate.

18. The wafer processing apparatus of claim 17, wherein the wafer processing apparatus is configured such that at a start of a heating process of the wafer, the separation distance measured by the distance sensor is a reference distance, and
when a distance measured by the distance sensor is a first distance that is less than the reference distance, the vacuum pressure is a first pressure, and
the chuck controller is configured to generate the flow control signal so that the vacuum pressure maintains the first pressure during the heating process of the wafer.

19. The wafer processing apparatus of claim 18, wherein the first distance is in a range from about 50 μm to about 200 μm.

20. A wafer processing apparatus comprising:
a plate which is divided into a central area and an edge area surrounding the central area and has a plurality of support pins configured such that a wafer is mounted on the plurality of support pins and a plurality of vacuum ports positioned between the plurality of support pins;
a heater configured to heat the plate;
a flow regulator configured to provide a vacuum pressure for fixing the wafer to the plurality of vacuum ports, and adjust a flow rate of a fluid flowing into the plurality of vacuum ports to be a target flow rate;
a pressure sensor arranged in the flow regulator and configured to measure the vacuum pressure;
a distance sensor for measuring a separation distance between a lower surface of the wafer and an upper surface of the plate in the edge area; and
a chuck controller configured to control the target flow rate of the fluid set in the flow regulator,
wherein the plurality of vacuum ports are located in the edge area,
the distance sensor and the pressure sensor are configured to transfer measured data to the chuck controller, and
the chuck controller is configured to generate a flow control signal for controlling the target flow rate of the fluid set in the flow regulator such that the vacuum pressure is constant during a heating process of the wafer.
